(19) United States
(12) Patent Application Publication
(10) Pub. No.: US 2026/0043664 A1
(43) Pub. Date: Feb. 12, 2026

(54) TRAJECTORY PREDICTION METHOD AND ELECTRONIC DEVICE

(71) Applicants: Hon Hai Precision Industry Co., Ltd., New Taipei City (TW); FOXCONN TECHNOLOGY GROUP CO., LTD, Shenzhen (CN)

(72) Inventors: Yung-Hui Li, New Taipei City (TW); Nien-Yi Jan, New Taipei City (TW); Yi-Rong Lin, New Taipei City (TW); Zikang Zhou, New Taipei City (TW); Haibo Hu, New Taipei City (TW); Xinhong Chen, New Taipei City (TW); Jianping Wang, New Taipei City (TW); Nan Guan, New Taipei City (TW)

(73) Assignees: Hon Hai Precision Industry Co., Ltd., New Taipei City (TW); FOXCONN TECHNOLOGY GROUP CO., LTD, Shenzhen (CN)

(21) Appl. No.: 19/218,638

(22) Filed: May 27, 2025

Related U.S. Application Data
(60) Provisional application No. 63/680,066, filed on Aug. 7, 2024.

(51) Int. Cl. G01C 21/34; G06F 30/27

(52) U.S. Cl. CPC G01C 21/3492; G06F 30/27

(57) ABSTRACT

A trajectory prediction method and an electronic device are provided. The trajectory prediction method includes: during a training phase, obtaining movement information of a plurality of agents at a plurality of time points, and dividing the time points into a plurality of training patches; selecting one of the training patches as a current training patch, obtaining at least one previous training patch preceding the current training patch, and predicting the current training patch according to the previous training patch to update parameters of a machine learning model; changing the current training patch to another training patch, and repeatedly performing the training phase to update the parameters of the machine learning model; and during an inference phase, inputting inference patches into the machine learning model to predict a first patch; and inputting the inference patches and the first patch into the machine learning model to predict a second patch.

### CROSS-REFERENCE TO RELATED APPLICATION

This application claims the priority benefit of U.S. application Ser. No. 63/680,066, filed on Aug. 7, 2024. The entirety of the above-mentioned patent application is hereby incorporated by reference herein and made a part of this specification.

### BACKGROUND

### Technical Field

The disclosure relates to a trajectory prediction method and an electronic device capable of performing agent simulation.

### Description of Related Art

With the rapid development of autonomous driving technology, how to evaluate the reliability of autonomous driving systems has become a key challenge. In current methods, road tests allow autonomous vehicles to interact directly with the real world, thereby measuring their driving performance. However, such tests face issues of high costs and the scarcity of safety-critical scenarios in the real world, which significantly limits the capability for large-scale and comprehensive evaluation. To address these limitations, system safety verification in simulated environments has gradually gained attention. Simulation testing may rapidly generate diverse driving scenarios at low cost, becoming one of the important methods for effectively evaluating the reliability of autonomous driving systems.

Among these, smart agent simulation technology is particularly important, which aims to simulate the behaviors of various traffic participants in the digital world, such as vehicles, pedestrians, and bicycles. Through smart agent simulation, the behavior of autonomous vehicles may be efficiently verified, and rapid iterations may be performed, thereby enhancing the overall performance and safety of the system. The development of such technology has significant implications for promoting large-scale application and commercialization of autonomous vehicles.

Existing learning-based agent simulators mainly draw on motion prediction technology, typically adopting an encoder-decoder architecture, as the technical characteristics of these two fields share similarities. Generally, these models use encoders to extract historical information, and use decoders to predict future states of agents based on encoded features. However, this method requires manually dividing multi-agent time series into historical and future patches, and processing them separately using encoders and decoders with different structures. This heterogeneous architecture design increases the complexity of model implementation and computational burden. Therefore, how to improve the structural design of smart agent simulators to reduce computational costs and enhance simulation efficiency has become an important direction in current research.

### SUMMARY

The disclosure proposes a trajectory prediction method and an electronic device, adopting an autoregressive architecture, which treats all time points as the present, allowing for more effective utilization of data.

The disclosure proposes a trajectory prediction method, adapted for an electronic device.

This trajectory prediction method contains: during a training phase, obtaining movement information of a plurality of agents at a plurality of time points, and dividing the time points into a plurality of training patches, where each training patch contains at least two time points; selecting one of the training patches as a current training patch, obtaining at least one previous training patch preceding the current training patch, and predicting the current training patch according to the previous training patch to update parameters of a machine learning model; changing the current training patch to another training patch, and repeatedly performing the training phase to update the parameters of the machine learning model; during an inference phase, obtaining a plurality of inference patches, and inputting the inference patches into the machine learning model to predict movement information of a first patch; and inputting the inference patches and the first patch into the machine learning model to predict movement information of a second patch.

In an embodiment of the disclosure, movement information of the inference patches contains a position, a velocity, and a yaw angle. The trajectory prediction method further contains: calculating a position difference, an angle vector difference, a yaw angle difference, and a time difference between two time points in the inference patches; and inputting the position difference, the angle vector difference, the yaw angle difference, and the time difference to a first neural network to obtain a relative feature vector.

In an embodiment of the disclosure, the trajectory prediction method further includes: generating a first query according to movement information of a latest time point of a last inference patch; generating a first key and a first value according to the relative feature vector between other time points and the latest time point of the last inference patch; and performing a multi-head self-attention algorithm according to the first query, the first key, and the first value to obtain a patch feature vector.

In an embodiment of the disclosure, the trajectory prediction method further includes: using the patch feature vector as a second query; generating a second key and a second value according to the relative feature vector between a plurality of time points of other inference patches and the latest time point; and performing a multi-head self-attention algorithm according to the second query, the second key, and the second value to obtain a time feature vector.

In an embodiment of the disclosure, the trajectory prediction method further includes: using the time feature vector as a third query; generating a third key and a third value according to a correlation between the movement information of the latest time point and a plurality of adjacent points on the map; and performing a multi-head cross-attention algorithm according to the third query, the third key, and the third value to obtain an agent-map feature vector.

In an embodiment of the disclosure, the agent-map feature vector belongs to a first agent, the trajectory prediction method further includes: using the agent-map feature vector as a fourth query; generating a fourth key and a fourth value according to an agent-map feature vector of a second agent and the patch feature vector between a plurality of time points of the last inference patch of the second agent and the latest time point; and performing a multi-head self-attention algorithm according to the fourth query, the fourth key, and the fourth value to obtain an agent to agent feature vector.

In an embodiment of the disclosure, the trajectory prediction method further includes: inputting the agent to agent feature vector to a second neural network to obtain probability values under a plurality of modes; and inputting the agent to agent feature vector to a recurrent neural network to predict movement information of a future patch.

From another angle, an embodiment of the disclosure proposes an electronic device, including a memory and a processor. The memory stores a plurality of instructions. The processor is communicatively connected to the memory for performing these instructions to complete the trajectory prediction method mentioned above.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1 is a schematic diagram illustrating an electronic device according to an embodiment.

FIG. 2 is a schematic diagram illustrating the division of a plurality of time points into patches according to an embodiment.

FIG. 3 to FIG. 5 are schematic diagrams illustrating the autoregressive architecture according to an embodiment.

FIG. 6 and FIG. 7 are schematic diagrams illustrating training patches during the training phase according to an embodiment.

FIG. 8 is a flowchart illustrating a trajectory prediction method according to an embodiment.

FIG. 9A and FIG. 9B are schematic diagrams illustrating the architecture of a machine learning model according to an embodiment.

FIG. 10 is a schematic diagram illustrating the three types of attention according to an embodiment.

### DESCRIPTION OF THE EMBODIMENTS

Some embodiments of the disclosure will be described in detail below with reference to the accompanying drawings. For reference numerals used in the following descriptions, same reference numerals in different accompanying drawings represent same or similar components. These embodiments are merely a part of the disclosure, and do not disclose all possible embodiments of the disclosure. More precisely, these embodiments are only examples of the systems and methods in the scope of patent application of the disclosure.

Moreover, terms such as “first” and “second” used herein do not represent order, and it should be understood that they are for differentiating devices or operations having the same technical terms.

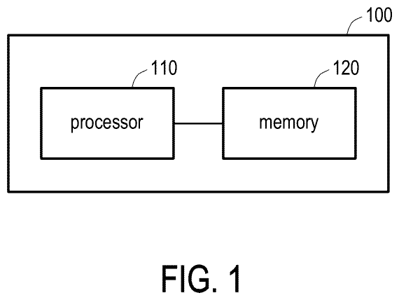

FIG. 1 is a schematic diagram illustrating an electronic device according to an embodiment. Referring to FIG. 1, an electronic device 100 may be a personal computer, laptop, server, distributed computer, cloud server, industrial computer, or various electronic devices with computing capabilities, etc., and the disclosure is not limited thereto. The electronic device 100 includes a processor 110 and a memory 120. The processor 110 is communicatively connected to the memory 120. Such communication connection may be achieved through any wired or wireless communication means, or may also be achieved through the Internet. The processor 110 may be a central processing unit, a microprocessor, a microcontroller, a digital signal processor, an image processing chip, a deep-learning processing unit (DPU), a neural network processing unit (NPU), a tensor processing unit (TPU), an application specific integrated circuit (ASIC), a programmable logic device (PLD), etc. The memory 120 may be random access memory, read-only memory, flash memory, floppy disk, hard disk, optical disc, USB flash drive, magnetic tape, or a database accessible through the Internet, which stores a plurality of instructions, and the processor 110 will execute these instructions to complete a trajectory prediction method. In the embodiment, the trajectory prediction method is used for agent simulation, with the purpose of predicting the trajectories of a plurality of agents at future time points. The agent may be a car, pedestrian, bicycle, or various vehicles. However, in other embodiments, the trajectory prediction method may also be used for self-driving cars, and the disclosure is not limited thereto.

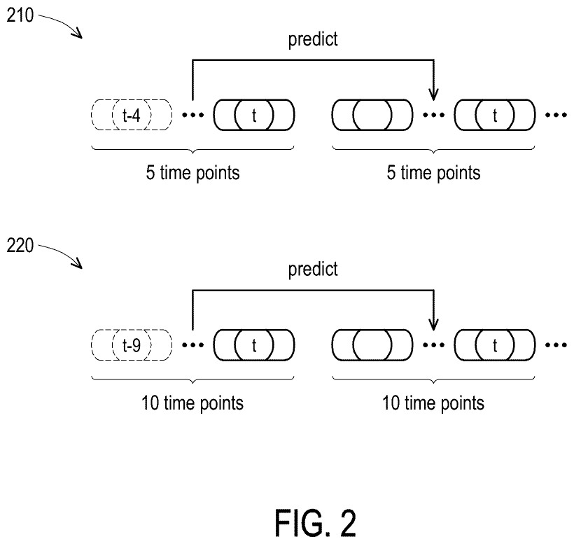

FIG. 2 is a schematic diagram illustrating the division of a plurality of time points into patches according to an embodiment. Referring to FIG. 2, the trajectory of an agent may be described as movement information at a plurality of time points, where the movement information may contain a position, a velocity, a yaw angle, a bounding box size, an agent type, etc. In some embodiments, the sampling frequency is 10 Hz, and thus there are 10 time points per second, but the disclosure does not limit the sampling frequency. Here, a plurality of time points will be divided into the same patch. For example, in setting 210, every 5 time points are divided into the same patch. Based on the movement information from time points t−4 to t, for example, the movement information for future time points t+1 to t+5 may be predicted, where t is a positive integer. Here, prediction of future trajectory is done on a patch basis. In other words, the movement information for a future patch may be predicted based on the movement information from one or more past patches. On the other hand, in setting 220, every 10 time points are divided into the same patch, thus predicting the movement information for the next 10 time points.

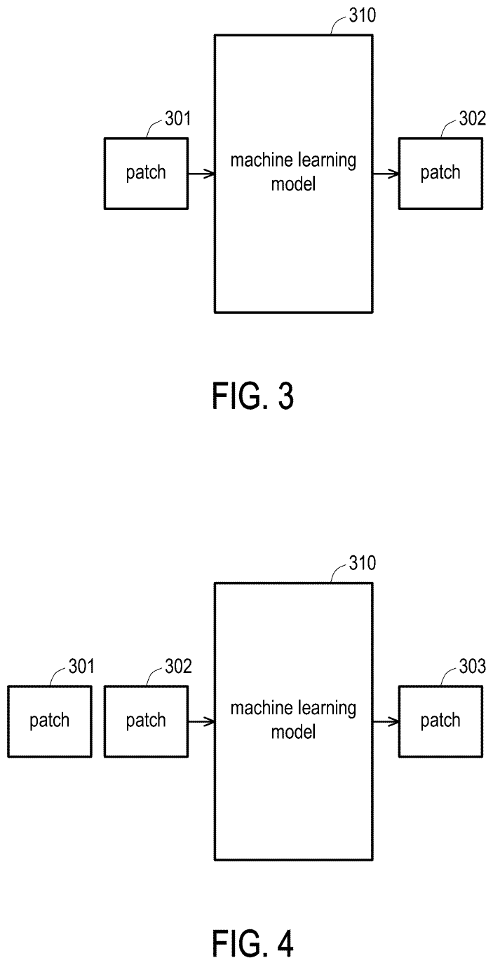

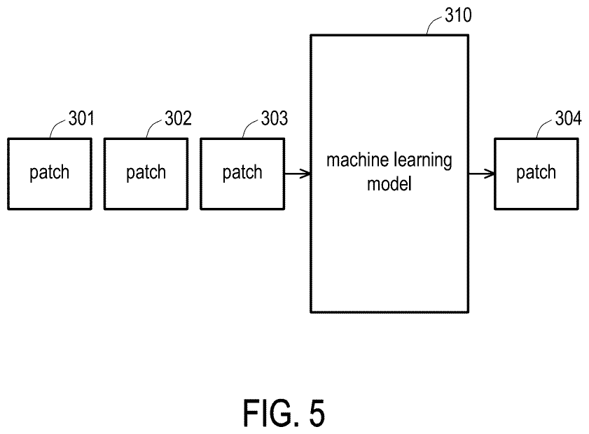

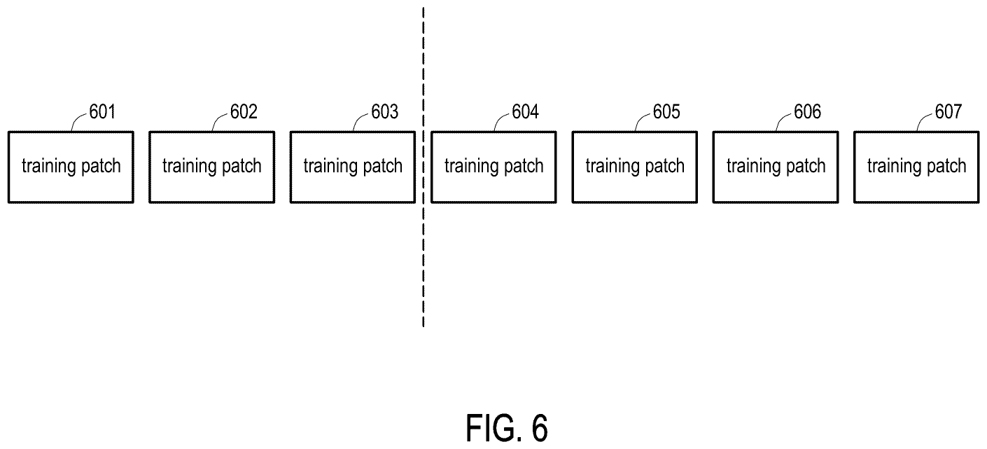

In this embodiment, an autoregressive architecture is adopted. FIG. 3 to FIG. 5 are schematic diagrams illustrating the autoregressive architecture according to an embodiment. Referring to FIG. 3, during the inference phase, when the movement information of a patch 301 is collected, the patch 301 may be input to a machine learning model 310 to predict the movement information in a next patch 302. Next, in FIG. 4, patches 301 and 302 may be input to the machine learning model 310 to predict the movement information of a next patch 303. In FIG. 5, patches 301-303 may be input to the machine learning model 310 to predict the movement information of a next patch 304, and so on. The input of the machine learning model 310 may contain movement information of a plurality of agents, and the output of the machine learning model 310 may contain movement information of one or more agents.

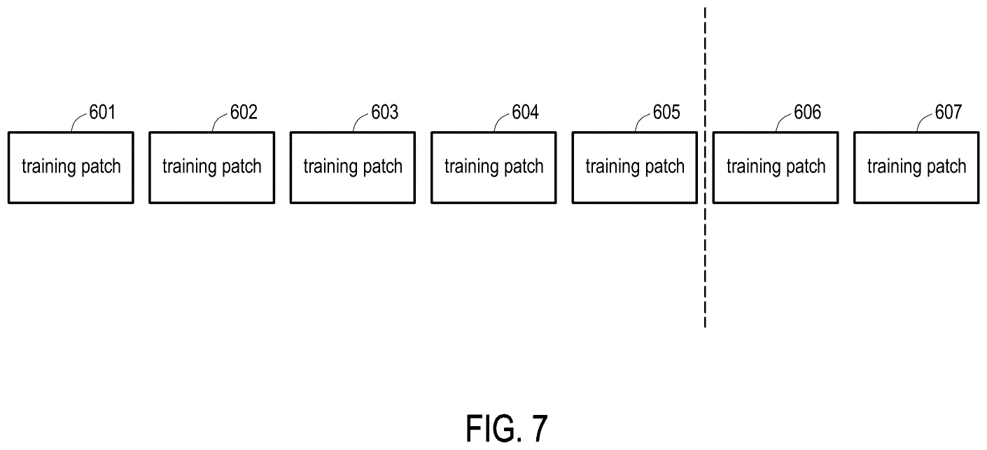

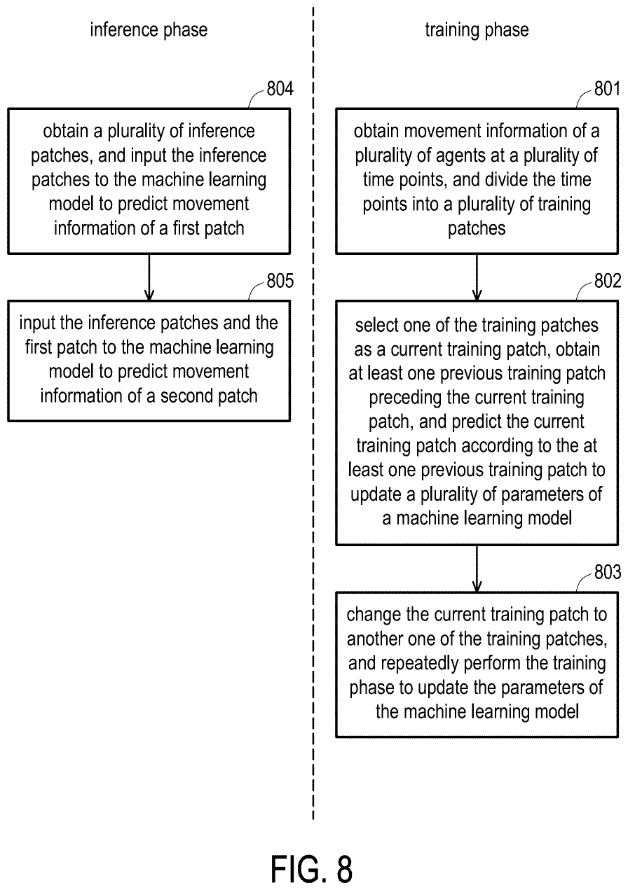

During the training phase, after obtaining movement information of a plurality of agents at a plurality of time points, the time points will be divided into a plurality of training patches, where each training patch contains at least two time points. Specifically, each training patch may be treated as a “current patch.” FIG. 6 and FIG. 7 are schematic diagrams illustrating training patches during the training phase according to an embodiment. Referring to FIG. 6, assuming there are 7 training patches 601-607, any training patch may be treated as the current patch (referred to as the current training patch). For example, a training patch 604 may be treated as the current training patch. Then, a plurality of training patches 601-603 (referred to as previous training patches) preceding the current training patch 604 are obtained. Next, the current training patch 604 may be predicted according to the previous training patches 601-603 to update a plurality of parameters of the machine learning model. In other words, in FIG. 6, the training patch 604 may serve as the ground truth. Next, another training patch may be selected as the current training patch (i.e., ground truth). For example, in FIG. 7, a training patch 606 is treated as the ground truth. Therefore, the training patches 601-605 are the previous training patches. Then the training phase may be repeatedly performed, predicting the current training patch 606 according to the previous training patches 601-605 to update the parameters of the machine learning model. Compared with known methods, since the current training patch may be arbitrarily designated, more samples may be generated. In addition, known technology needs to manually distinguish between “history” and “future,” with the encoder processing history and the decoder processing future, while the method disclosed here does not have the concept of history and future, and instead treats all training patches as current patches.

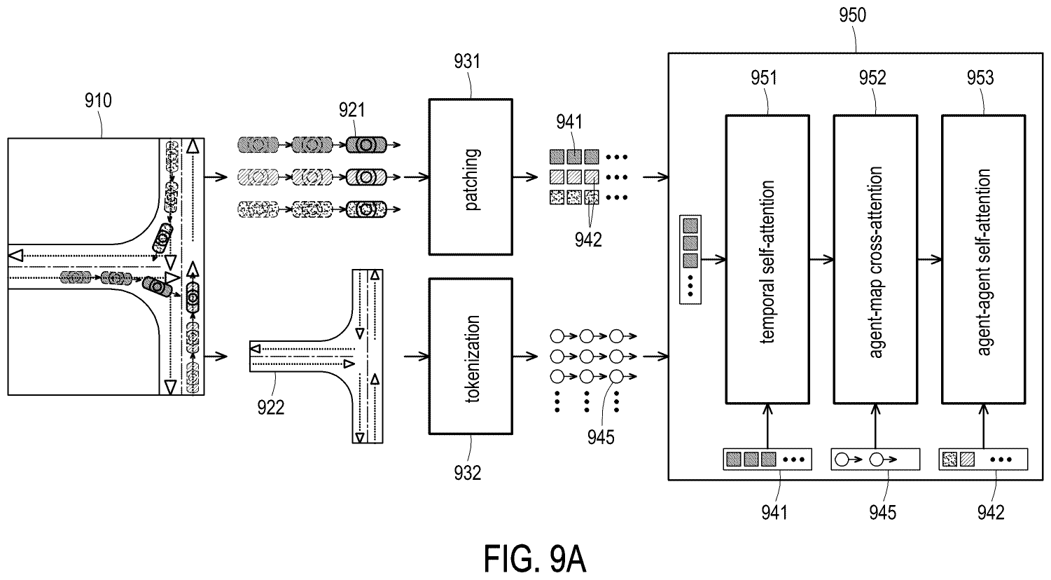

FIG. 8 is a flowchart illustrating a trajectory prediction method according to an embodiment. Referring to FIG. 8, the training phase includes steps 801-803, while the inference phase includes steps 804 and 805. In step 801, movement information of a plurality of agents at a plurality of time points is obtained, and the time points are divided into a plurality of training patches. In step 802, one of the training patches is treated as the current training patch, at least one previous training patch preceding the current training patch is obtained, and the current training patch is predicted according to the previous training patch to update a plurality of parameters of the machine learning model. In step 803, the current training patch is changed to another training patch, and the training phase is repeatedly performed to update the parameters of the machine learning model. In step 804, inference patches are obtained and input to the machine learning model to predict movement information of a first patch. In step 805, the inference patches and the first patch are input to the machine learning model to predict movement information of a second patch. However, the steps in FIG. 8 may be performed individually or combined with other steps; in other words, other steps may be added before, between, or after the steps in FIG. 8.

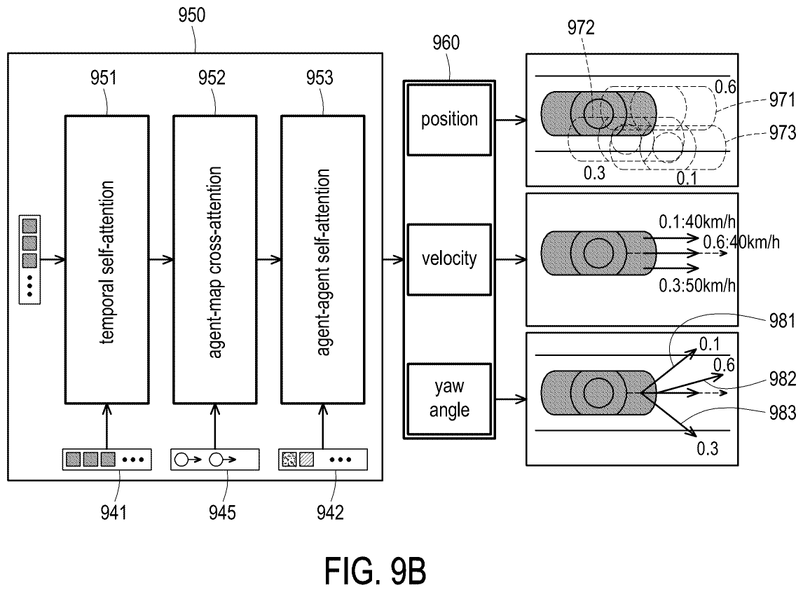

FIG. 9A and FIG. 9B are schematic diagrams illustrating the architecture of a machine learning model according to an embodiment. Referring to FIG. 9A and FIG. 9B, first a traffic scene 910 is obtained, then agent data 921 and map data 922 are extracted from the traffic scene 910. The agent data 921 contains movement information of a plurality of agents at a plurality of time points, where the movement information includes a position, a velocity, a yaw angle, a bounding box size, and an agent type (for example pedestrian, vehicle, bicycle, etc.). In step 931, patching is performed on the agent data 921, which means dividing a plurality of time points into the same patch. From another angle, here a patch is defined as the following mathematical formula 1.

$$[ Mathematical Formula 1 ]$$

$${P}_{i}^{τ} = {S}_{i}^{( τ - 1 ) \times ℓ + 1 : τ \times ℓ} , i ∈ \{ 1 , … , {N}_{agent} \} , τ ∈ \{ 1 , … , {N}_{patch} \}$$

In the above formula, [symbol] represents the number of time points contained in one patch; N_{patch} represents the number of patches; N_{agent} is the number of agents; Sᵢ represents the movement information (or state) of the i-th agent;

$${S}_{i}^{( τ - 1 ) \times ℓ + 1 : τ \times ℓ}$$

represents the movement information of the i-th agent from the (τ−1)× [symbol] +1 time point to the τ× [symbol] time point; and

$${P}_{i}^{τ}$$

represents the trajectory of the i-th agent in the τ-th patch. Below, P^{τ} is used to represent the trajectory of the entire scene in the τ-th patch, as shown in the following mathematical formula 2.

$${P}^{τ} = {S}_{1 : {N}_{agent}}^{( τ - 1 ) \times ℓ + 1 : τ \times ℓ} , τ ∈ \{ 1 , … , {N}_{patch} \} \qquad [ Mathematical Formula 2 ]$$

In other words, P^{τ} contains the movement information of all agents in the τ-th patch. The problem disclosed in the disclosure is described as the following mathematical formula 3, where the joint distribution of a plurality of agents is decomposed, while assuming that the decisions between different agents are independent.

$$\begin{matrix}Pr ( {S}_{1 : {N}_{agent}}^{1 : T} \vert M ) = Pr ( {P}^{1 : {N}_{patch}} \vert M ) \\ = {\prod }_{τ = 1}^{{N}_{patch}} Pr ( {P}^{τ} \vert {P}^{1 : τ - 1} , M ) \\ = {\prod }_{τ = 1}^{{N}_{patch}} {\prod }_{i = 1}^{{N}_{agent}} Pr ( {P}_{i}^{τ} \vert {P}^{1 : τ - 1} , M )\end{matrix} \qquad [ Mathematical Formula 3 ]$$

On the other hand, there are a plurality of possibilities for each agent's trajectory, and each possibility is referred to as a mode. After adding the mode to mathematical formula 3, it may be rewritten as the following mathematical formula 4.

$$\begin{matrix}P r ( {P}_{i}^{τ} \vert {P}^{1 : τ - 1} , M ) = \begin{matrix}{\sum }_{k = 1}^{{N}_{mode}} {π}_{i , k}^{τ} Pr ( {P}_{i , k}^{τ} \vert {P}^{1 : τ - 1} , M )\end{matrix} \\ = {\sum }_{k = 1}^{{N}_{mode}} {π}_{i , k}^{τ} Pr ( {S}_{i , k}^{( τ - 1 ) \times ℓ + 1 : τ \times ℓ} \vert {P}^{1 : τ - 1} , M ) \\ = {\sum }_{k = 1}^{{N}_{mode}} {π}_{i , k}^{τ} {\prod }_{t = ( τ - 1 ) \times ℓ + 1}^{τ \times ℓ} Pr ( {S}_{i , k}^{t} \vert {S}_{i , k}^{( τ - 1 ) \times ℓ + 1 : t - 1} , {P}^{1 : τ - 1} , M )\end{matrix} \qquad [ Mathematical Formula 4 ]$$

In the above formula,

$${π}_{i , k}^{τ}$$

is the probability is the probability that the i-th agent belongs to the k-th mode in the τ-th patch. In FIG. 9A, after patching is performed, agent embedding may be generated. The agent embedding contains movement information 941 and 942 of a plurality of agents at a plurality of time points, where the movement information 941 belongs to the agent currently being predicted, and the movement information 942 belongs to other agents.

On the other hand, map data 922 contains classifications such as road centerlines, road edges, sidewalks, obstacles, etc. In step 932, tokenization is performed on the map data 922 to generate map embedding. In some embodiments, the map data 922 may be divided into a plurality of areas, with the size of each area being, for example, 5 square meters, but the disclosure is not limited thereto. In addition, the road centerlines, road edges, sidewalks, etc. mentioned above may be described as a line segment, where the beginning and the end of this line segment each have their own coordinates (including x coordinate and y coordinate), and subtracting the beginning coordinate from the end coordinate results in a vector with dimension 2. A token 945 of a certain area on the map contains the position, the vector mentioned above, the angle of this vector, etc. The map embedding contains tokens for each area.

Next, both the agent embedding and the map embedding are input to a decoder 950. During the training phase, the agent embedding contains movement information of the training patch. During the inference phase, the agent embedding contains movement information of the inference patch. For simplicity, “patch” is used below to represent “training patch” or “inference patch”.

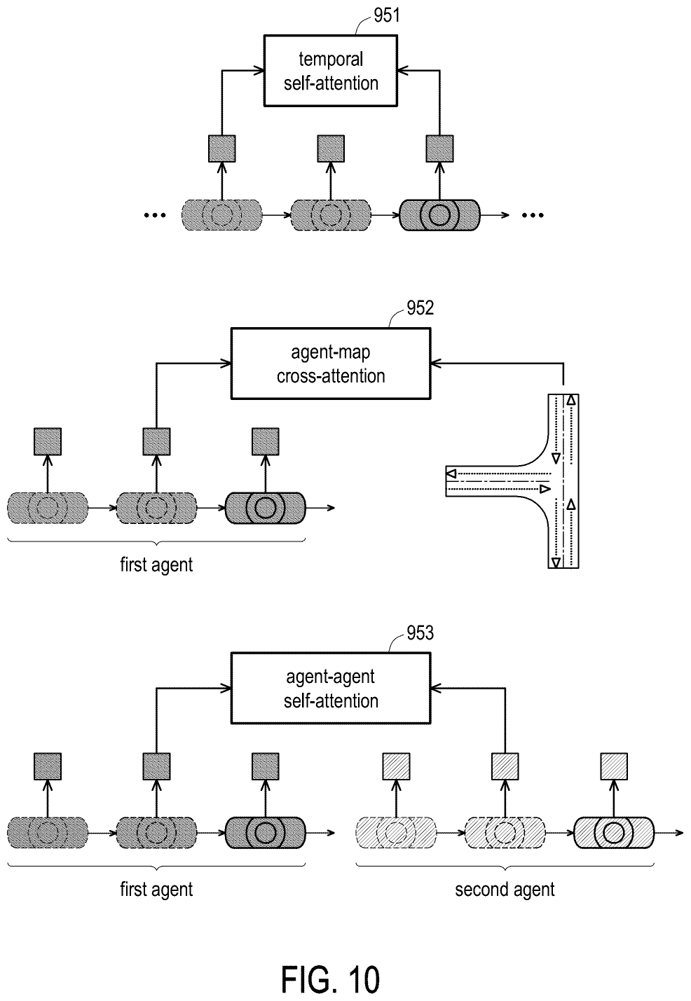

The decoder 950 calculates three types of attention, namely temporal self-attention 951, agent-map cross-attention 952, and agent-agent self-attention 953. FIG. 10 is a schematic diagram illustrating the three types of attention according to an embodiment. Referring to FIG. 10, the temporal self-attention 951 is used to calculate attention between the same agent at different time points. The agent-map cross-attention 952 is used to calculate attention between agents and the map. The agent-agent self-attention 953 is used to calculate attention between different agents. The calculation of these three types of attention will be explained in detail below.

First, the details as to how to calculate the relationship between two movement information is explained. Below, i and j are used to represent different movement information (for example, movement information at different time points, but it may also be movement information of different agents). Please refer to the following mathematical formula 5.

$${ℛ}_{j \to i} = MLP ( ‖ {d}_{j \to i} ‖ , ∠ ( {n}_{i} , {d}_{j \to i} ) , {Δθ}_{j \to i} , {Δτ}_{j \to i} ) \qquad [ Mathematical Formula 5 ]$$

In the above formula, ∥d_{j→i}∥ is the position difference between two pieces of movement information; Δθ_{j→i} is the yaw angle difference between two pieces of movement information, where θ is the yaw angle; an angle vector may be represented as nᵢ=[cosθ, sinθ]; <(nᵢ, d_{j→i}) represents the angle between vector nᵢ and vector d_{j→i}, which is referred to as the angle vector difference between two pieces of movement information; and Δτ_{j→i} is the time difference between two pieces of movement information. By inputting the above position difference, angle vector difference, yaw angle difference, and time difference into a neural network MLP ( ) the relationship between two pieces of movement information, [symbol] _{j→i}, also referred to as the relative feature vector, may be obtained.

Next, a first query is generated based on the movement information of the latest time point of the last patch. A first key and a first value are generated based on the relative feature vector between other time points and the latest time point of the last patch. The multi-head self attention (MHSA) algorithm is performed based on the first query, the first key, and the first value to obtain a patch feature vector. Specifically, the above calculation may be represented as the following mathematical formula 6.

$${\hat{P}}_{i}^{τ} = MHSA ( Q = {\hat{S}}_{i}^{τ \times ℓ} , K = V = {\{ [ {\hat{S}}_{i}^{t} , {ℛ}_{i}^{t \to τ \times ℓ} ] \}}_{t ∈ \{ ( τ - 1 ) \times ℓ + 1 , … , τ \times ℓ - 1 \}} ) \qquad [ Mathematical Formula 6 ]$$

In the above formula, τ× [symbol] represents the latest time point; Q is the first query; K is the first key; and V is the first value. In some embodiments, the movement information may be input into a neural network to obtain vector

$${\hat{S}}_{i}^{t}$$

so as to project the movement information to a higher dimension. In addition, in the above formula, [:,:] represents the concatenation between two vectors; and

$${\hat{P}}_{i}^{τ}$$

is referred to as the patch feature vector. The calculation may be viewed as integrating information from other time points of the last patch into the latest time point.

Next, the above patch feature vector

$${\hat{P}}_{i}^{τ}$$

is used as a second query. A second key and a second value are generated based on the relative feature vector between time points of patches other than the last patch and the above latest time point. Then, the multi-head self attention algorithm is performed based on the second query, the second key, and the second value to obtain the time feature vector. Specifically, the calculation may be represented as the following mathematical formula 7.

$${F}_{a 2 t , i}^{τ} = MHSA ( Q = {\hat{P}}_{i}^{τ} , K = V = {\{ [ {\hat{P}}_{i}^{t} , {ℛ}_{i}^{t \times ℓ \to τ \times ℓ} ] \}}_{t ∈ \{ 1 , … , τ - 1 \}} ) \qquad [ Mathematical Formula 7 ]$$

In the above formula, MHSA ( ) has a causal mask, calculating the attention only between each patch and its previous patches; and

$${F}_{a 2 t , i}^{τ}$$

is referred to as the time feature vector. The calculation may be viewed as integrating information from other patches into the last patch. This completes the calculation of temporal self-attention 951.

Next, the agent-map cross-attention 952 is explained. The above time feature vector

$${F}_{a 2 t , i}^{τ}$$

is used as the third query. A third key and a third value are generated based on a correlation between the movement information of the latest time point and a plurality of adjacent points on the map. Then, the multi-head cross-attention (MHCA) algorithm is performed based on the third query, the third key, and the third value to obtain an agent-map feature vector. Specifically, the above calculation may be represented as the following mathematical formula 8.

$${F}_{a 2 m , i}^{τ} = MHCA ( Q = {F}_{a 2 t , i}^{τ} , K = V = {\{ [ {\hat{M}}_{j} , {ℛ}_{j \to i}^{τ \times ℓ} ] \}}_{j ∈ κ ( i , τ )} ) \qquad [ Mathematical Formula 8 ]$$

In the above formula, \hat{M}ⱼ represents the feature vector generated by the jth token in the map;

$${ℛ}_{j \to i}^{τ \times ℓ}$$

represents the correlation between the jth token on the map and the latest time point. Specifically, a plurality of adjacent points on the map may be obtained according to the position of the latest time point. These adjacent points are represented as [symbol] (i, τ), and the disclosure does not limit the number of adjacent points. Additionally, the tokens on the map also contain position and a two-dimensional vector, so they can also be substituted into the above mathematical formula 5 to calculate correlation. The difference is that since the map has no time information, the time difference Δτ_{j→i} will not be calculated. In addition, in the above formula,

$${F}_{a 2 m , i}^{τ}$$

is the agent-map feature vector. The calculation may be viewed as integrating information from adjacent points on the map into the latest time point.

Next, the agent-agent self-attention 953 is explained. The above calculation is about the first agent, while other agents are referred to as the second agents. The agent-map feature vector

$${F}_{a 2 m , i}^{τ}$$

or the first agent is used as the fourth query. A fourth key and a fourth value are generated based on the agent-map feature vector

$${F}_{a 2 m , j}^{τ}$$

of the second agents and the relative feature vector between the time points of the last patch of the second agents and the latest time point of the first agent (using mathematical formula 5). Then, the multi-head self-attention algorithm is performed based on the fourth query, the fourth key, and the fourth value to obtain an agent to agent feature vector. The calculation may be represented as the following mathematical formula 9.

$$[ Mathematical Formula 9 ]$$

$$F {}_{a 2 a , i}^{τ} = MHSA ( Q = F {}_{a 2 m , i}^{τ} , K = V = \{ [ F {}_{a 2 m , j}^{τ} , ℛ {}_{j \to i}^{τ \times ℓ} ] \} j ∈ κ ( i , τ ) )$$

In the above formula, [symbol] (i, τ) represents other second agents adjacent to the first agent, and the disclosure does not limit the number of second agents;

$${F}_{a 2 a , i}^{τ}$$

is the agent to agent feature vector, which may be viewed as integrating information from other second agents into the first agent.

For simplification,

$$F {}_{i}^{τ}$$

is used below to represent the feature vector output by the decoder 950 (for example, identical to the agent to agent feature vector

$${F}_{a 2 a , i}^{τ} ) .$$

Next, an output 960 of the first agent may be generated according to the feature vector

$${F}_{i}^{τ} .$$

The output 960 contains the position, velocity, and yaw angle at the next time point. Specifically, inputting the feature vector

$${F}_{i}^{τ}$$

to a neural network may get probability values under a plurality of modes. Then, the feature vector

$${F}_{i}^{τ}$$

is input to a recurrent neural network (RNN) to predict movement information for a future patch. Specifically, the above calculation may be represented as the following mathematical formula 10.

$$[ Mathematical Formula 10 ]$$

$$π = {}_{i}^{τ + 1} softmax ( MLP ( F {}_{i}^{τ} ) )$$

$$h {}_{i}^{τ , 1} = F {}_{i}^{τ} ,$$

$$μ {}_{i}^{τ \times ℓ + t} , b {}_{i}^{τ \times ℓ + t} = MLP ( h {}_{i}^{τ , t} ) ,$$

$$h {}_{i}^{τ , t + 1} = RNN ( h {}_{i}^{τ , t} , μ {}_{i}^{τ \times ℓ + t} )$$

In the above formula,

$${π}_{i}^{τ + 1}$$

is a vector, containing probability values under a plurality of modes;

$${h}_{i}^{τ , t}$$

is the hidden state of the recurrent neural network RNN ( ) and b and μ are parameters of the probability distribution, where in some embodiments, Laplace probability distribution may be adopted, while in other embodiments, Gaussian distribution may also be adopted. Here, the parameters of the probability distribution are to be predicted, from which the position, velocity, and yaw angle may be obtained through sampling or calculating expected values. In other words, the output of the neural network MLP ( ) contains three parameters b and three parameters μ, corresponding to the position, velocity, and yaw angle, respectively. In FIG. 9B, outputs under a plurality of modes are illustrated. For example, the probabilities of three positions 971-973 are 0.6, 0.3, and 0.1, respectively. In addition, the velocities under three modes are 40 km/h, 50 km/h, and 40 km/h, respectively. The probabilities of three yaw angles 981-983 are 0.1, 0.6, and 0.3, respectively. Here, the mode with the highest probability may be adopted as the final output, or sampling from these modes may also be used to determine the final output.

In some embodiments, the loss function adopted during the training phase is represented as the following mathematical formula 11.

$${ℒ}_{NLL} = {\sum }_{τ = 1}^{{N}_{patch}} {\sum }_{i = 1}^{{N}_{agent}} - log {\sum }_{k = 1}^{{N}_{mode}} π {}_{i , k}^{τ} {\prod }_{t = ( τ - 1 ) \times ℓ + 1}^{τ \times ℓ} Pr ( S {}_{i , k}^{t} \vert S {}_{i , k}^{( τ - 1 ) \times ℓ + 1 ; t - 1} , {P}^{1 : τ - 1} , M )$$

During the training process, teacher forcing is used to parallelize the modeling of predicting the next patch and reduce learning difficulty, but the real (ground-truth) agent state is not used when updating the hidden state of the recurrent neural network, with the purpose of training the model to recover from prediction errors.

In the above trajectory prediction method and electronic device, there is no need to manually divide the training data into history and future, and more training samples may be generated. In addition, the design of a patch and the adoption of an autoregressive architecture help predict trajectories over a long time.

Although the disclosure has been described with reference to the embodiments above, the embodiments are not intended to limit the disclosure. Any person skilled in the art can make some changes and modification without departing from the spirit and scope of the disclosure. Therefore, the scope of the disclosure will be defined in the appended claims.

What is claimed is:

1. A trajectory prediction method, adapted for an electronic device, wherein the trajectory prediction method comprises:
during a training phase, obtaining movement information of a plurality of agents at a plurality of time points, and dividing the time points into a plurality of training patches, wherein each of the training patches comprises at least two of the time points;
selecting one of the training patches as a current training patch, obtaining at least one previous training patch preceding the current training patch among the training patches, and predicting the current training patch according to the at least one previous training patch to update a plurality of parameters of a machine learning model;
changing the current training patch to another one of the training patches, and repeatedly performing the training phase to update the parameters of the machine learning model;
during an inference phase, obtaining a plurality of inference patches, and inputting the inference patches to the machine learning model to predict movement information of a first patch; and
inputting the inference patches and the first patch to the machine learning model to predict movement information of a second patch.

2. The trajectory prediction method according to claim 1, wherein movement information of the inference patches comprises a position, a velocity, and a yaw angle, and the trajectory prediction method further comprises:
calculating a position difference, an angle vector difference, a yaw angle difference, and a time difference between two time points in the inference patches; and
inputting the position difference, the angle vector difference, the yaw angle difference, and the time difference to a first neural network to obtain a relative feature vector.

3. The trajectory prediction method according to claim 2, further comprising:
generating a first query according to movement information of a latest time point of a last one of the inference patches;
generating a first key and a first value according to the relative feature vector between other time points and the latest time point of the last one of the inference patches; and
performing a multi-head self-attention algorithm to obtain a patch feature vector according to the first query, the first key, and the first value.

4. The trajectory prediction method according to claim 3, further comprising:
using the patch feature vector as a second query;
generating a second key and a second value according to the relative feature vector between a plurality of time points of other inference patches of the inference patches and the latest time point; and
performing the multi-head self-attention algorithm to obtain a time feature vector according to the second query, the second key, and the second value.

5. The trajectory prediction method according to claim 4, further comprising:
using the time feature vector as a third query;
generating a third key and a third value according to a correlation between the movement information of the latest time point and a plurality of adjacent points on a map; and
performing a multi-head cross-attention algorithm to obtain an agent-map feature vector according to the third query, the third key, and the third value.

6. The trajectory prediction method according to claim 5, wherein the agent-map feature vector belongs to a first agent, and the trajectory prediction method further comprises:
using the agent-map feature vector as a fourth query;
generating a fourth key and a fourth value according to an agent-map feature vector of a second agent and the relative feature vector between a plurality of time points of the last one of the inference patches of the second agent and the latest time point; and
performing the multi-head self-attention algorithm to obtain an agent to agent feature vector according to the fourth query, the fourth key, and the fourth value.

7. The trajectory prediction method according to claim 6, further comprising:
inputting the agent to agent feature vector to a second neural network to obtain probability values under a plurality of modes; and
inputting the agent to agent feature vector to a recurrent neural network to predict movement information of a future patch.

8. An electronic device, comprising:
a memory, configured to store a plurality of instructions; and
a processor, communicatively connected to the memory for performing the instructions to complete a plurality of steps:
during a training phase, obtaining movement information of a plurality of agents at a plurality of time points, and dividing the time points into a plurality of training patches, wherein each of the training patches comprises at least two of the time points;
selecting one of the training patches as a current training patch, obtaining at least one previous training patch preceding the current training patch among the training patches, and predicting the current training patch according to the at least one previous training patch to update a plurality of parameters of a machine learning model;
changing the current training patch to another one of the training patches, and repeatedly performing the training phase to update the parameters of the machine learning model;
during an inference phase, obtaining a plurality of inference patches, and inputting the inference patches to the machine learning model to predict movement information of a first patch; and
inputting the inference patches and the first patch to the machine learning model to predict movement information of a second patch.

9. The electronic device according to claim 8, wherein movement information of the inference patches comprises a position, a velocity, and a yaw angle, and the steps further comprise:
calculating a position difference, an angle vector difference, a yaw angle difference, and a time difference between two time points in the inference patches; and
inputting the position difference, the angle vector difference, the yaw angle difference, and the time difference to a first neural network to obtain a relative feature vector.

10. The electronic device according to claim 9, wherein the steps further comprise:
generating a first query according to movement information of a latest time point of a last one of the inference patches;
generating a first key and a first value according to the relative feature vector between other time points and the latest time point of the last one of the inference patches; and
performing a multi-head self-attention algorithm to obtain a patch feature vector according to the first query, the first key, and the first value.

11. The electronic device according to claim 10, wherein the steps further comprise:
using the patch feature vector as a second query;
generating a second key and a second value according to the relative feature vector between a plurality of time points of other inference patches of the inference patches and the latest time point; and
performing the multi-head self-attention algorithm to obtain a time feature vector according to the second query, the second key, and the second value.

12. The electronic device according to claim 11, wherein the steps further comprise:
using the time feature vector as a third query;
generating a third key and a third value according to a correlation between the movement information of the latest time point and a plurality of adjacent points on a map; and
performing a multi-head cross-attention algorithm to obtain an agent-map feature vector according to the third query, the third key, and the third value.

13. The electronic device according to claim 12, wherein the agent-map feature vector belongs to a first agent, and the steps further comprise:
using the agent-map feature vector as a fourth query;
generating a fourth key and a fourth value according to an agent-map feature vector of a second agent and the relative feature vector between a plurality of time points of the last one of the inference patches of the second agent and the latest time point; and
performing the multi-head self-attention algorithm to obtain an agent to agent feature vector according to the fourth query, the fourth key, and the fourth value.

14. The electronic device according to claim 13, wherein the steps further comprise:
inputting the agent to agent feature vector to a second neural network to obtain probability values under a plurality of modes; and
inputting the agent to agent feature vector to a recurrent neural network to predict movement information of a future patch.
